(19) United States
(12) Patent Application Publication
(10) Pub. No.: US 2025/0336706 A1
(43) Pub. Date: Oct. 30, 2025

(54) DEVICE AND METHOD WITH ARTIFICIAL INTELLIGENCE-BASED WAFER ROTATION

(71) Applicant: Samsung Electronics Co., Ltd., Suwon-si (KR)

(72) Inventors: Seungbeom KIM, Suwon-si (KR); Suhyun SHIN, Suwon-si (KR); Gyeryang JO, Suwon-si (KR); Youjin HAN, Suwon-si (KR); Young-Seok CHOI, Suwon-si (KR)

(73) Assignee: Samsung Electronics Co., Ltd., Suwon-si (KR)

(21) Appl. No.: 19/192,173

(22) Filed: Apr. 28, 2025

(30) Foreign Application Priority Data
Apr. 30, 2024 (KR) 10-2024-0057513
Jul. 12, 2024 (KR) 10-2024-0092459

(51) Int. Cl. H01L 21/677; H01L 21/66; H01L 21/68

(52) U.S. Cl. CPC H01L 21/67796; H01L 21/68; H01L 22/12; H01L 22/34

(57) ABSTRACT

An artificial intelligence-based wafer rotation method according to an embodiment includes receiving measurement data of a manufacturing process from a data measurement module integrated into manufacturing equipment, calculating rotation angle of a wafer for each process step that maximizes manufacturing yield of the manufacturing process based on the measurement data, and rotating the wafer at the calculated rotation angle in at least one of process steps.

### CROSS-REFERENCE TO RELATED APPLICATIONS

This application claims priority to and the benefit of Korean Patent Application No. 10-2024-0057513 filed at the Korean Intellectual Property Office on Apr. 30, 2024, and Korean Patent Application No. 10-2024-0092459 filed at the Korean Intellectual Property Office on Jul. 12, 2024, the entire contents of which are incorporated herein by reference.

### BACKGROUND

### 1. Field

The present disclosure relates to a device and method with artificial intelligence-based wafer rotation.

### 2. Description of Related Art

In conventional semiconductor manufacturing processes, defect root cause analysis typically involves selecting a process step suspected as the source of anomalies through empirical evaluation or statistical modeling. To validate the suspected step, comparative analysis against reference data is often performed using wafer rotation techniques. This approach relies on aligning process variables with historical or theoretical datasets to isolate deviations, but its execution is inherently constrained by dependencies on the selected process step and the rotational methodology employed.

However, typical methodologies for implementing wafer rotation exhibit significant variability across semiconductor fabrication tool manufacturers and equipment models. For example, a method of performing wafer rotation computationally using Recipe Control Program (RCP), a method of shutting down the equipment and modifying the configuration, etc.), and certain methods require extensive cross-disciplinary coordination among engineering personnel, prolonged diagnostic timelines, and unavoidable production downtime, resulting in production loss.

### SUMMARY

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

In one general aspect, an artificial intelligence-based wafer rotation method includes generating measurement data of a manufacturing process through a data measurement module integrated into manufacturing equipment; calculating, based on the measurement data, a rotation angle of a wafer for each process step that maximizes manufacturing yield; and rotating the wafer at the calculated rotation angle in at least one of process steps.

The calculating of the rotation angle of the wafer for each process step may include determining different rotation angles applied at each process step to identify defect causes for defects occurring at an initial alignment angle of the wafer.

The calculating of the rotation angle of the wafer for each process step may comprise determining, based on the measurement data, a first process step where a first defective region is detected and a second process step where a second defective region is detected among the process steps; and determining a first rotation angle for the first process step or a second rotation angle for the second process step such that the first defective region and the second defective region overlap.

The rotating of the wafer at the rotation angle of the wafer for each process step may comprise assigning the calculated rotation angle as a process condition for each process step using a sequence recipe (SEQ RCP).

The rotating of the wafer at the rotation angle of the wafer for each process step may comprise rotating the wafer via an aligner within an Equipment Front End Module (EFEM) at each process step.

The measurement data may comprise at least one of: critical dimension (CD), optical critical dimension (OCD), thickness (THK), dielectric constant (k value), inspection (INSP), and energy-dispersive spectroscopy (EDS) related to the manufacturing yield, and wherein the data measurement module may include integrated metrology (IM).

The method may further comprise generating an image or coordinating data indicating a defective region of the wafer based on the measurement data.

The calculating of the rotation angle of the wafer for each process step may comprise determining the rotation angle based on the measurement data, the image, or the coordinating data at each process step.

The calculating of the rotation angle of the wafer for each process step may comprise determining a rotation angle required to control a distribution in an etching process step based on film thickness distribution data of the wafer.

The method may further comprise re-collecting second measurement data for each process step after wafer rotation according to the calculated rotation angle; and recalculating the rotation angle of the wafer for each process step based on the collected second measurement data to further optimize the manufacturing yield.

In one general aspect, an artificial intelligence-based wafer rotation device includes a data measurement module that generates measurement data of a manufacturing process; a rotation angle calculation module that computes a rotation angle of a wafer for each process step to maximize manufacturing yield based on the measurement data; and a wafer rotation module that rotates the wafer by the calculated rotation angle at least once during each one of process steps.

The rotation angle calculation module may determine different rotation angles applied at each process step to identify defect cause of defects associated with an initial alignment angle of the wafer.

The rotation angle calculation module may determine, based on the measurement data, a first process step where a first defective region is detected and a second process step where a second defective region is detected among the process steps; and determine a first rotation angle for the first process step or a second rotation angle for the second process step such that the first defective region and the second defective region overlap.

The device may further comprise a controller that assigns the calculated rotation angle as a process condition for each process step using a sequence recipe (SEQ RCP).

The wafer rotation module may rotate the wafer using an aligner within an Equipment Front End Module (EFEM) at each process step.

The data measurement module may comprise integrated metrology (IM); and the measurement data may comprise at least one of: critical dimension (CD), optical critical dimension (OCD), thickness (THK), dielectric constant (k value), inspection (INSP), and energy-dispersive spectroscopy (EDS) related to the manufacturing yield.

The artificial intelligence model may generate an image or coordinating data indicating a defective region of the wafer based on the measurement data.

The rotation angle calculation module may determine the rotation angle based on the measurement data, the image, or the coordinating data at each of the process steps.

The rotation angle calculation module may calculate a rotation angle required to control a distribution in an etching process step based on film thickness distribution data of the wafer.

The rotation angle calculation module may re-collect second measurement data for each process step after wafer rotation according to the calculated rotation angle; and re-calculate the rotation angle of the wafer for each process step based on the collected second measurement data to further optimize the manufacturing yield.

### BRIEF DESCRIPTION OF THE DRAWINGS

FIG. 1 schematically illustrates a semiconductor manufacturing system using an artificial intelligence-based wafer rotation device according to one or more embodiments.

FIG. 2 is a block diagram illustrating an artificial intelligence-based wafer rotation device according to one or more embodiments.

FIGS. 3 to 5 are flowcharts of an artificial intelligence-based wafer rotation method according to one or more embodiments.

FIG. 6 illustrates how to discover the cause of defects according to one or more embodiments.

FIGS. 7A and 7B illustrate optimization of process distribution according to one or more embodiments.

FIG. 8 illustrates how to accumulate defective regions and minimize the defective rate according to one or more embodiments.

FIG. 9 illustrates a manufacturing equipment according to one or more embodiments.

FIG. 10 is a block diagram describing a computing device according to one or more embodiments.

### DETAILED DESCRIPTION

The following detailed description is provided to assist the reader in gaining a comprehensive understanding of the methods, apparatuses, and/or systems described herein. However, various changes, modifications, and equivalents of the methods, apparatuses, and/or systems described herein will be apparent after an understanding of the disclosure of this application. For example, the sequences of operations described herein are merely examples, and are not limited to those set forth herein, but may be changed as will be apparent after an understanding of the disclosure of this application, with the exception of operations necessarily occurring in a certain order. Also, descriptions of features that are known after an understanding of the disclosure of this application may be omitted for increased clarity and conciseness.

The features described herein may be embodied in different forms and are not to be construed as being limited to the examples described herein. Rather, the examples described herein have been provided merely to illustrate some of the many possible ways of implementing the methods, apparatuses, and/or systems described herein that will be apparent after an understanding of the disclosure of this application.

The terminology used herein is for describing various examples only and is not to be used to limit the disclosure. The articles “a,” “an,” and “the” are intended to include the plural forms as well, unless the context clearly indicates otherwise. As used herein, the term “and/or” includes any one and any combination of any two or more of the associated listed items. As non-limiting examples, terms “comprise” or “comprises,” “include” or “includes,” and “have” or “has” specify the presence of stated features, numbers, operations, members, elements, and/or combinations thereof, but do not preclude the presence or addition of one or more other features, numbers, operations, members, elements, and/or combinations thereof.

Throughout the specification, when a component or element is described as being “connected to,” “coupled to,” or “joined to” another component or element, it may be directly “connected to,” “coupled to,” or “joined to” the other component or element, or there may reasonably be one or more other components or elements intervening therebetween. When a component or element is described as being “directly connected to,” “directly coupled to,” or “directly joined to” another component or element, there can be no other elements intervening therebetween. Likewise, expressions, for example, “between” and “immediately between” and “adjacent to” and “immediately adjacent to” may also be construed as described in the foregoing.

Although terms such as “first,” “second,” and “third”, or A, B, (a), (b), and the like may be used herein to describe various members, components, regions, layers, or sections, these members, components, regions, layers, or sections are not to be limited by these terms. Each of these terminologies is not used to define an essence, order, or sequence of corresponding members, components, regions, layers, or sections, for example, but used merely to distinguish the corresponding members, components, regions, layers, or sections from other members, components, regions, layers, or sections. Thus, a first member, component, region, layer, or section referred to in the examples described herein may also be referred to as a second member, component, region, layer, or section without departing from the teachings of the examples.

Unless otherwise defined, all terms, including technical and scientific terms, used herein have the same meaning as commonly understood by one of ordinary skill in the art to which this disclosure pertains and based on an understanding of the disclosure of the present application. Terms, such as those defined in commonly used dictionaries, are to be interpreted as having a meaning that is consistent with their meaning in the context of the relevant art and the disclosure of the present application and are not to be interpreted in an idealized or overly formal sense unless expressly so defined herein. The use of the term “may” herein with respect to an example or embodiment, e.g., as to what an example or embodiment may include or implement, means that at least one example or embodiment exists where such a feature is included or implemented, while all examples are not limited thereto.

The artificial intelligence models (AI models) described herein are machine learning models that learn at least one task and can be implemented as a computer program (executable instructions or executable code) executed by one or more processors. The task learned by the AI model may involve solving a problem through machine learning or a work to be performed through machine learning. AI models may be implemented as computer programs that run on computing devices, downloaded over a network, or sold in a product form. Alternatively, the AI model(s) may be connected to various devices through a network. Also, the AI model(s) may be interoperable with various devices through a network.

model.

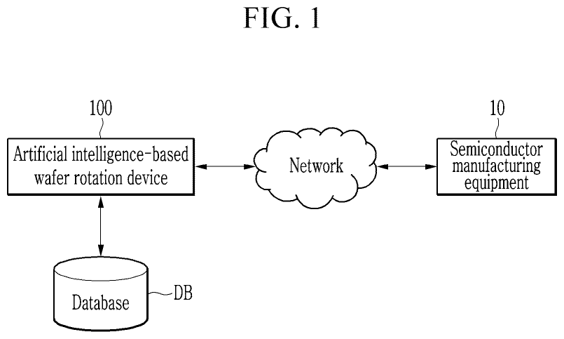

FIG. 1 schematically illustrates a semiconductor manufacturing system utilizing an artificial intelligence (AI)-based wafer rotation device according to one or more embodiments.

Referring to FIG. 1, a semiconductor manufacturing system may include a semiconductor manufacturing equipment 10, an AI-based wafer rotation device 100, and a database (DB).

The semiconductor manufacturing equipment 10 may include a plurality of apparatuses configured to perform sequential process steps for semiconductor chip fabrication.

For example, the process steps may include, but not limited to, wafer manufacturing, oxidation, photolithography, etching, deposition, metal wiring, and quality inspection.

The semiconductor manufacturing equipment 10 may further comprise ancillary systems such as an equipment front end module (EFEM) and an automated material handling system (AMHS) for facilitate wafer transport, loading, and unloading across process steps.

Each apparatus within the semiconductor manufacturing equipment 10 is specialized to perform a specific process step, operating collaboratively to transform wafers into finalized semiconductor products.

The AI-based wafer rotation device 100 is configured to rotate a wafer in the process of dynamically adjusting wafer orientation during alignment prior to the wafer being supplied to each apparatus of the semiconductor manufacturing equipment 10.

The AI-based wafer rotation device 100 may be communicatively coupled to the semiconductor manufacturing equipment 10 via a network and be independently controlled by a centralized server.

The AI-based wafer rotation device 100 may be programmed to calculate a wafer rotation angle for each process step and transmit the rotation angle to one or more semiconductor manufacturing equipment units 10.

For example, the AI-based wafer rotation device 100 may interface with an EFEM aligner to adjust wafer orientation (e.g., rotate a wafer) during the process of loading and unloading the wafer into apparatus of the semiconductor manufacturing equipment 10.

The AI-based wafer rotation device 100 may correct wafer alignment and computes rotation angles for each process step during the wafer alignment by analyzing measurement data generated by the semiconductor manufacturing equipment 10.

The AI-based wafer rotation device 100 may further optimize product yield by calculating/deriving rotation angles for each process step based on real-time and historical the measurement data.

The AI-based wafer rotation device 100 may train an artificial intelligence model, using the measurement data, to automatically calculate and determine the rotation angle of the wafer for each process step to maximize product yield.

The AI-based wafer rotation device 100 may generate a process-specific rotation angle parameter for each step, which is dynamically applied during wafer alignment.

During alignment at each process step, the AI-based wafer rotation device 100 may rotate a wafer to an optimal rotation angle defined by the generated rotation angle parameters, when the wafer is aligned at each process step through the semiconductor manufacturing equipment 10.

The database (DB) aggregates and stores measurement data as structured big data, serving as a repository for historical and real-time process metrics. The database (DB) may provide measurement data required to calculate the rotation angle for each process step.

The database (DB) may be operatively connected to the AI-based wafer rotation device 100 and supply measurement data critical for rotation angle computation.

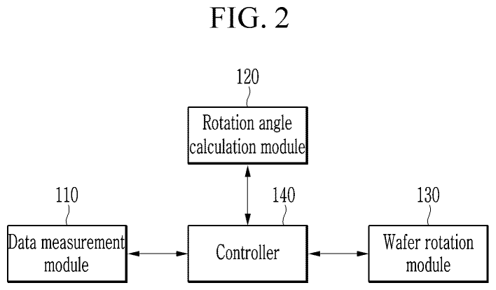

FIG. 2 is a block diagram of an AI-based wafer rotation device according to an embodiment of the present disclosure.

Referring to FIG. 2, the AI-based wafer rotation device 100 may include a data measurement module 110, a rotation angle calculation module 120, a wafer rotation module 130, and a controller 140, each representing distinct functional components of the system.

The data measurement module 110, the rotation angle calculation module 120, the wafer rotation module 130, and the controller 140 are communicatively interconnected via wired or wireless networks to enable synchronized operation.

The data measurement module 110 may generate real-time measurement data corresponding to the current angular orientation of a wafer during semiconductor fabrication.

In one embodiment, the data measurement module 110 may include integrated metrology (IM) systems. Integrated metrology (IM) refers to a measurement apparatus integrated directly into the semiconductor manufacturing equipment (10, see FIG. 1) to perform in-situ, real-time measurement of wafers during the semiconductor manufacturing process.

The data measurement module 110 may be operatively coupled to one or more semiconductor manufacturing equipment units 10, each equipped with dedicated IM systems.

The data measurement module 110 may be configured to measure and collect semiconductor product yield metrics, including but not limited to structural, electrical, and compositional properties of wafers processed by the semiconductor manufacturing equipment 10.

For example, the measurement data may include critical dimension (CD), optical critical dimension (OCD), thickness (THK), dielectric constant (k value), inspection (INSP) metrics, and energy-dispersive spectroscopy (EDS) data.

The rotation angle calculation module 120 may dynamically compute the rotation angle of the wafer for each process step to optimize manufacturing yield, based on measurement data acquired by the data measurement module 110.

In one implementation, the rotation angle calculation module 120 may be implemented as an independent computational server that executes a predefined algorithm to derive rotation angles for each process step.

The rotation angle calculation module 120 may employ one or more machine learning algorithms to automatically determine/calculate the optimal rotation angle tailored for each process step.

During defect root cause analysis, the rotation angle calculation module 120 may identify deviations correlated with the initial wafer alignment angle and calculate distinct rotation angles for subsequent process inspection steps to mitigate defect propagation.

The rotation angle calculation module 120 may further utilize AI-driven image or data analysis models to generate an image or a map, including graphical representations or coordinating data (e.g., coordinates), indicating defective region(s) of the wafer based on measurement data.

In an example, the rotation angle calculation module 120 may identify a first process step in which a first defective region is found and a second process step in which a second defective region is found among the process steps based on the measurement data using the AI-driven image or data analysis models.

The rotation angle calculation module 120 may determine a first rotation angle of the first process step and a second rotation angle of the second process step to spatially align the first and second defective regions, so that the first defective region and the second defective region overlap, thereby minimizing cumulative yield loss.

The rotation angle calculation module 120 may calculate the rotation angle based on measurement data and the image or the coordinating data of the map at each process step.

For example, in an etching process step, the rotation angle calculation module 120 may calculate the rotation angle required for controlling a distribution based on measurement data on the distribution of the film thickness of the wafer.

The rotation angle calculation module 120 may collect a second measurement data for each process step on the rotated wafer according to the rotation angle, and repeatedly perform an algorithm to calculate the rotation angle required for maximizing yield using the collected second measurement data.

The wafer rotation module 130 may rotate the wafer to precisely adjust wafer orientation at each process step according to the rotation angles computed by the rotation angle calculation module 120.

In one embodiment, the wafer rotation module 130 may operatively interface with an aligner integrated within an equipment front-end module (EFEM) to rotate the wafer at a specific rotation angle at each process step.

The wafer rotation module 130 may command rotation at a rotation angle calculated in the EFEM. Alternatively, the wafer rotation module 130 may be implemented as an aligner within the EFEM.

Alternative implementations may integrate the wafer rotation module 130 directly into semiconductor manufacturing equipment (10, FIG. 1), with configurations adaptable to diverse fabrication tool architectures model.

The wafer rotation module 130 may rotate and align the wafer at each process step using process-specific rotation angles received from the rotation angle calculation module 120.

The controller 140 may perform data exchange and operational coordination among the data measurement module 110, the rotation angle calculation module 120, and the wafer rotation module 130.

The controller 140 may further facilitate communication and control between the AI-based wafer rotation device 100 and the semiconductor manufacturing equipment (10, FIG. 1), acting as a centralized command hub.

For example, the controller 140 may assign the calculated rotation angles to the wafer rotation module 130 as process-specific parameters via a sequence recipe (SEQ RCP), ensuring seamless integration with fabrication workflows.

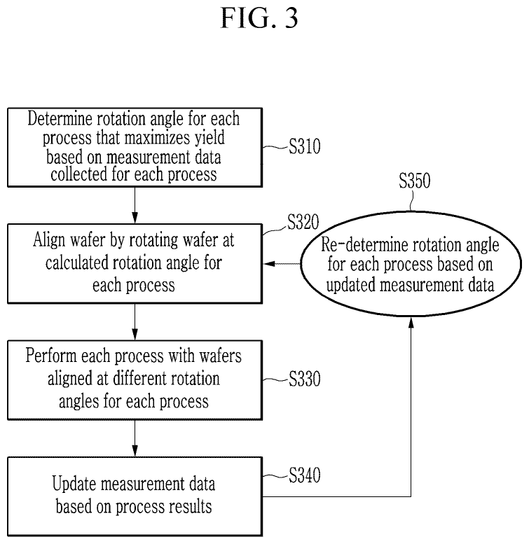

FIGS. 3 to 5 illustrate flowcharts of an AI-based wafer rotation method according to one or more embodiments. The method depicted in FIGS. 3 to 5 may be performed by the AI-based wafer rotation device 100 of FIG. 1.

In FIG. 3, the AI-based wafer rotation device 100 may determine a process-specific rotation angle to optimize manufacturing yield based on measurement data collected for each process step (S310).

The AI-based wafer rotation device 100 may align a wafer by rotating the wafer at a determined rotation angle prior to initiating each process step (S320).

The AI-based wafer rotation device 100 may perform each process with wafers aligned at different/distinct rotation angles tailored to their respective process requirements (S330).

The AI-based wafer rotation device 100 may dynamically update measurement data based on process results (S340).

The AI-based wafer rotation device 100 may re-determine the rotation angle for each process based on updated measurement data, establishing a closed-loop optimization framework (S350).

The AI-based wafer rotation device 100 calculates the rotation angle for each process step based on the database (DB, see FIG. 1) storing real-time measurement data acquired from manufacturing equipment during wafer processing at varied rotational orientations.

The AI-based wafer rotation device 100 calculates a process-specific rotation angle for each process step and applies the process-specific rotation angle to manufacturing equipment, ensuring alignment with yield optimization objectives.

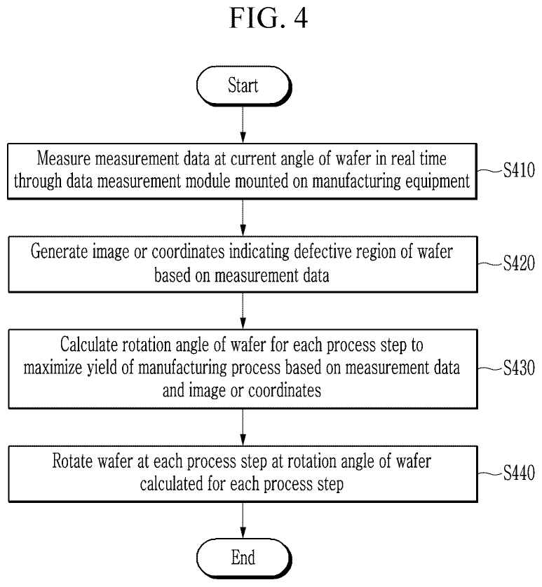

In FIG. 4, the AI-based wafer rotation device 100 may acquire/measure real-time measurement data corresponding to the current angular orientation of the wafer via a data measurement module mounted on or integrated into the manufacturing equipment (S410).

The data measurement module may employ integrated metrology (IM) to collect yield-critical metrics, including critical dimension (CD), optical critical dimension (OCD), thickness (THK), dielectric constant (k value), inspection (INSP), and energy-dispersive spectroscopy (EDS) data.

The AI-based wafer rotation device 100 may generate defect images or maps including coordinating data indicating defective region(s) of a wafer by processing measurement data through an AI-driven image or data analysis model (S420).

The AI-based wafer rotation device 100 may compute the rotation angle(s) of the wafer for each process step to maximize the yield of the manufacturing process based on the measurement data and the defect images or coordinating data (S430).

The AI-based wafer rotation device 100 may rotate the wafer at each process step at the rotation angle of the wafer calculated for each process step, ensuring optimal alignment prior to processing (S440).

In an example, the AI-based wafer rotation device 100 may adjust wafer orientation by rotating the wafer to a specific rotation angle during wafer loading into a process-specific manufacturing apparatus.

For example, wafer rotation is executed by an aligner within an equipment front-end module (EFEM), which receives angular parameters from the AI-based wafer rotation device 100.

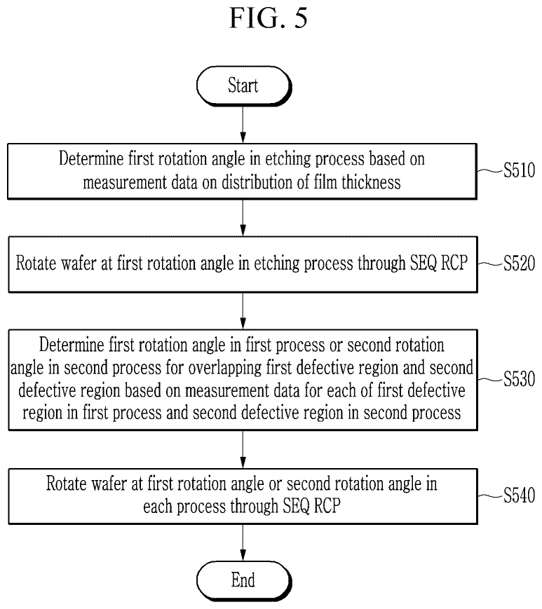

In FIG. 5, the AI-based wafer rotation device 100 may determine the first rotation angle for a process step based on measurement data on the distribution of the film thickness (S510), and applies the first rotation angle to the wafer a sequence recipe (SEQ RCP) protocol (S520).

The AI-based wafer rotation device 100 may assign the rotation angle calculated for each process step as a process condition for each process step using SEQ RCP, a predefined sequence recipe governing the order and parameters of semiconductor fabrication steps.

SEQ RCP ensures process consistency and reproducibility by defining sequential process steps and associated parameters during wafer processing.

The AI-based wafer rotation device 100 may determine the first rotation angle in the first process or the second rotation angle in the second process for overlapping the first defective region and the second defective region based on measurement data for each of the first defective region in the first process and the second defective region in the second process (S530).

The AI-based wafer rotation device 100 may detect images or coordinating data of defective regions of the wafer using an AI-based wafer image analysis or data analysis algorithm based on measurement data.

The AI-based wafer rotation device 100 may calculate the first rotation angle and/or the second rotation angle for spatially overlapping the first defective region and the second defective region based on images or coordinating data of the detected first defective region and the second defective region, thereby minimizing cumulative yield loss.

The AI-based wafer rotation device 100 may rotate the wafer at the first rotation angle or the second rotation angle through the SEQ RCP (S540).

Defect localization is achieved through AI-driven wafer image analysis or data analytics, which isolates defective regions and assigns coordinate-based identifiers (coordinating data). Rotation angles are derived algorithmically to align defective regions across process steps, thereby reducing variability and enhancing yield. The calculated rotation angles are transmitted to manufacturing equipment via SEQ RCP, ensuring seamless integration into the fabrication workflow.

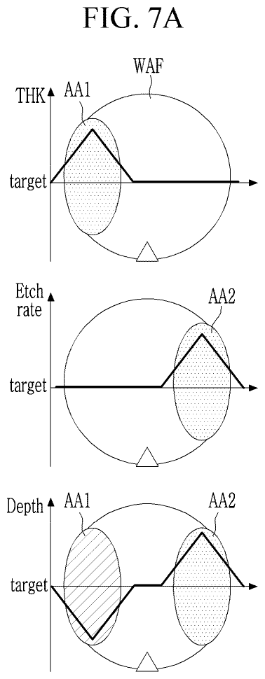

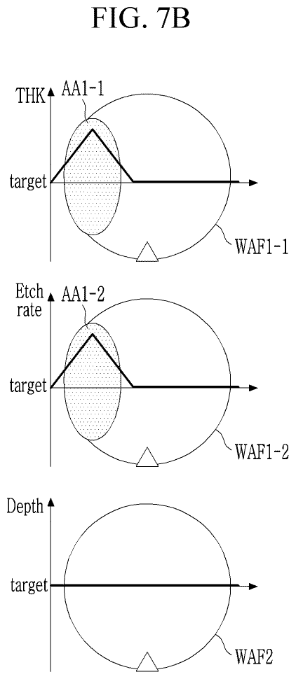

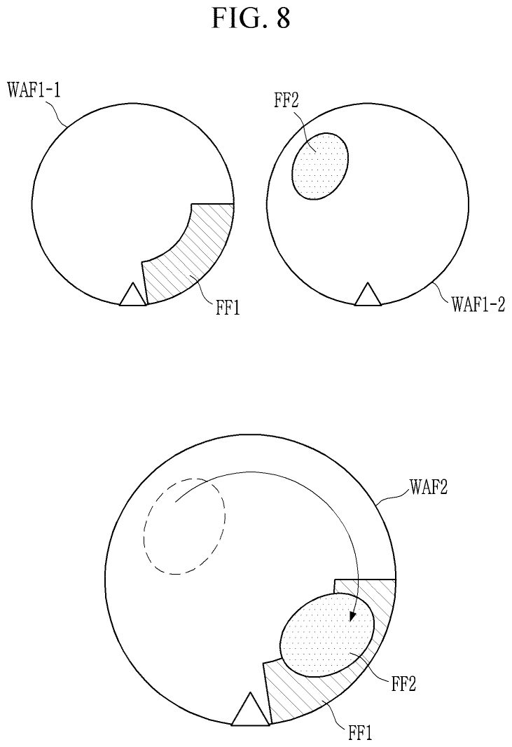

Refer to the description of the embodiments of FIGS. 7 and 8.

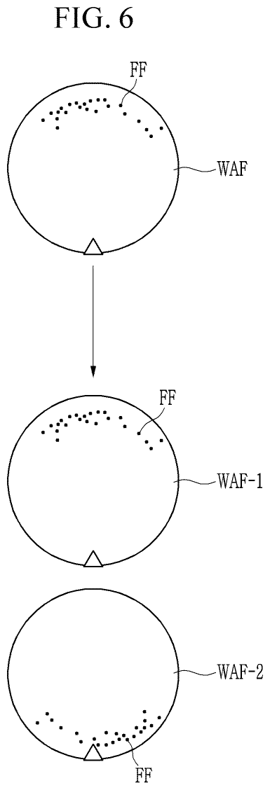

FIG. 6 illustrates a method for detecting the cause of defects in semiconductor manufacturing according to one or more embodiments.

The AI-based wafer rotation device 100 may calculate distinct/different rotation angles applied at each process step during defect diagnostics of detecting/discovering the cause of defects for defects occurring at the initial wafer alignment angle.

The AI-based wafer rotation device 100 may identify the position (e.g., spatial coordinates) of a specific defect FF on a wafer WAF obtained through multiple steps at an initial alignment angle.

The AI-based wafer rotation device 100 may compute the first rotation angle for a first wafer WAF-1 supplied to the first process step and the second rotation angle for a second wafer WAF-2 supplied to the second process step among a plurality of process steps in the step of discovering the cause of defects.

The first rotation angle and the second rotation angle may be independently determined as different arbitrary values to isolate process-specific defects.

The AI-based wafer rotation device 100 may introduce the first wafer WAF-1, rotated at the first rotation angle, into the process apparatus performing the first process step.

The AI-based wafer rotation device 100 may introduce the second wafer WAF-2, rotated at the second rotation angle, into the process apparatus performing the second process step.

In FIG. 6, the position of the defect FF on the first wafer WAF-1 is the same as the position of the initial defect. The position of the defect FF on the second wafer WAF-1 is different from the position of the initial defect. In other words, the defect FF on the first wafer WAF-1 retains its initial position, whereas the defect on the second wafer (WAF-2) shifts spatially.

Therefore, this positional variance confirms that the defect FF originates in the second process step.

The AI-based wafer rotation device 100 may identify that a defect has occurred in the second process step and determine the cause of the defect as the apparatus performing the second process step.

FIGS. 7A and 7B illustrate process distribution optimization, wherein FIG. 7(A) represents a comparative example and FIG. 7(B) illustrates a process distribution according to one or more embodiments.

The AI-based wafer rotation device 100 may calculate the wafer rotation angle for etching process steps based on measurement data on the distribution of the film thickness of the wafer.

FIG. 7(A) depicts measurement data on the distribution of the film thickness of a wafer according to a comparative example.

The y-axis THK in FIG. 7(A) indicates the film thickness of each wafer region of the wafer WAF. Etch rate indicates an etching rate in the etching step. Depth is the depth of the wafer WAF that has gone through the manufacturing process. The target indicates the optimized thickness distribution of the wafer. In FIG. 7(A), before the etching step, the thickness of the wafer appears thicker in a first region AA1 than in other regions. Then, in the etching step, the etching rate of a second region AA2 is greater than that of the first region AA1. This is because the etching process is performed on the entire wafer, and the thickness of the first region AA1 was thicker than that of the second region AA2 before the etching process.

As a result, the depth of the wafer WAF appears larger in the second region AA2 than in the first region AA1. That is, the comparative example exhibits an asymmetrical film thickness profile, such that pre-etch thickness in region AA1 exceeds other regions, while etching rates in region AA2 are elevated, resulting in non-uniform post-etch depths.

In the comparative example, the wafer WAF is aligned as is without being rotated during the etching step, regardless of the film thickness distribution of the wafer WAF. Therefore, the thickness of the wafer WAF that has undergone the etching step appears asymmetrical.

FIG. 7(B) depicts measurement data on the distribution of the film thickness of a wafer according to one or more embodiments.

The AI-based wafer rotation device 100 may determine the rotation angle by identifying the thickness of a film on a wafer and the distribution of an etching amount of etching equipment.

The AI-based wafer rotation device 100 may determine the rotation angle in the etching step by identifying the degree of crystallinity (hardness) of the film and the distribution of the etching amount of the etching equipment.

In FIG. 7(B), the AI-based wafer rotation device 100 determines the film thickness distribution for a wafer WAF1-1 before being input into the etching step through measurement data.

The thickness of a first region AA1-1 of the embodiment is greater than that of the other regions.

The AI-based wafer rotation device 100 determines the distribution of the etching amount in the etching step through measurement data.

The etching rate of the first region AA1-1 of the embodiment is greater than that of other regions.

The AI-based wafer rotation device 100 may calculate the rotation angle required for a wafer WAF1-2 input in the etching step to make the thickness of the wafer symmetrical.

The AI-based wafer rotation device 100 rotates the wafer WAF1-2 input in the etching step at a required rotation angle. For example, the AI-based wafer rotation device 100 may rotate the wafer WAF1-2 by 180 degrees.

Therefore, according to an embodiment, the thickness of a wafer WAF2 that has undergone the etching step is symmetrical. By rotating wafer WAF1-2 by 180 degrees prior to etching, the AI-based wafer rotation device 100 achieves symmetrical thickness in post-etch wafer WAF2, optimizing material uniformity.

FIG. 8 illustrates a method of how to accumulate defective regions and minimize the defective rate according to an embodiment of the present disclosure.

The AI-based wafer rotation device 100 may identify the first process step in which the first defective region is found and the second process step in which the second defective region is found among the process steps based on the measurement data

The AI-based wafer rotation device 100 may determine the first rotation angle of the first process step or the second rotation angle of the second process step so that the first defective region and the second defective region overlap.

In FIG. 8, in the wafers WAF1-1, WAF1-2 according to the comparative example, a defect 1 FF1 that occurred in the first process step and a defect 2 FF2 that occurred in the second process step appear in different positions.

For example, the defect 1 FF1 and the defect 2 FF2 appear at 180 degrees from the center of the wafer.

That is, in the comparative example, the defect FF1 in the wafer WAF1-1 that has gone through the first process step and the defect FF2 in the wafer WAF1-2 that has gone through the second process step occur at different positions, thereby reducing the yield of the wafer.

However, the AI-based wafer rotation device 100 according to an embodiment may rotate the wafer WAF1-2 by a rotation angle of 180 degrees in the second process step after the first process step so that the defect 2 FF2 and the defect 1 FF1 overlap, thereby minimizing cumulative yield loss.

Alternatively, the AI-based wafer rotation device 100 may rotate the wafer WAF1-1 of the first process step by 180 degrees so that the defect 1 FF1 of the first process step and the defect 2 FF2 overlap, thereby minimizing cumulative yield loss.

When the defect 2 FF2 and the defect 1 FF1 overlap, product yield may increase.

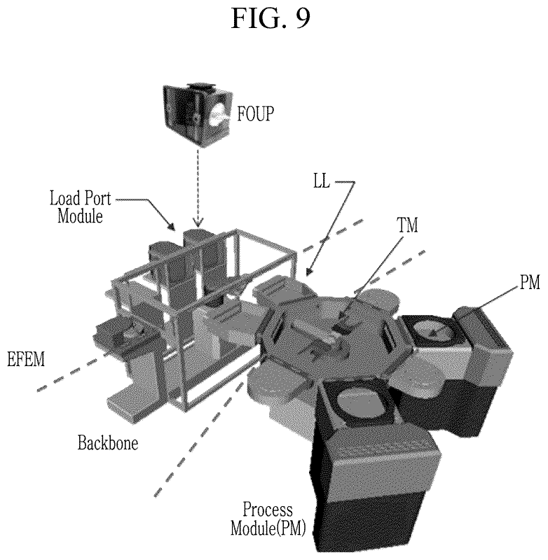

FIG. 9 illustrates a manufacturing equipment according to one or more embodiments. In FIG. 9, a chamber-type equipment is illustrated.

The manufacturing equipment of FIG. 9 includes the EFEM, a backbone, and a process module PM.

The EFEM performs the function of wafer handling. The EFEM automatically moves wafers from a load port to the processing apparatus and then returns the wafers to the load port after processing.

Additionally, the EFEM performs alignment and inspection functions. The EFEM may check to determine that the wafers are properly aligned and inspect the wafers for defects or contamination.

The EFEM may be integrated with various semiconductor equipment units and controlled centrally. For example, the EFEM may be controlled through the AI-based wafer rotation device 100.

The EFEM may include a load port module.

The load port module may load or discharge wafers loaded into a front opening unified pod (FOUP) into the load port.

The backbone transports wafers safely and efficiently to each process step. The backbone may include a robot arm and a transport module TM.

The processing apparatus of the robot arm moves the wafers.

The transport module TM moves the wafers between the EFEM and the process module PM. The transport module can operate in combination with a robot arm.

The process module PM may include a plurality of apparatuses, each performing a manufacturing process.

The plurality of process modules PM may each perform a specific process (for example, etching, deposition, ion implantation).

The AI-based wafer rotation device 100 rotates the wafer to a rotation angle in the aligner of the EFEM. The wafers are then moved to the transport module and the process module of the equipment for further processing.

Then, the AI-based wafer rotation device 100 collects data through a measurement device, calculates the optimal wafer rotation angle using an advanced AI algorithm based on the data, and uses the value as input when performing the next rotation.

The AI-based wafer rotation device 100 rotates the next wafer to be input in advance using an aligner in the same equipment while the first wafer input from a single lot is still in process.

Therefore, losses may be minimized from a production perspective.

In other words, the AI-based wafer rotation device 100 may be controlled through centralized control using a single UI for all equipment manufacturers and devices, rather than being controlled through different UIs and controllers for each equipment manufacturer and device. For example, by utilizing IM, it is possible to obtain measurement data on the rotation results for each process step in real time, store and utilize the measurement data in a database, and suggest the optimal rotation angle (wafer rotation angle) from a yield perspective for each process step through an advanced AI algorithm.

Ultimately, if the AI-based wafer rotation device 100 is used to apply the optimal rotation angle of the wafer in all process steps, the product yield may be improved not only in semiconductor process technology but also in equipment technology.

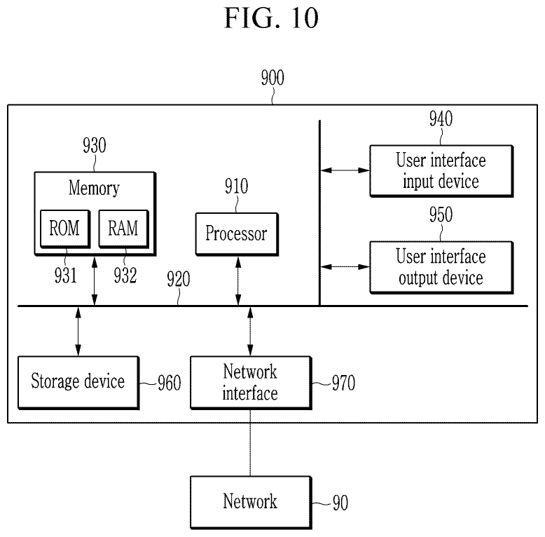

FIG. 10 depicts a computing device according to one or more embodiments.

Referring to FIG. 10, the AI-based wafer rotation device and method according to the embodiments may be implemented using a computing device 900.

The computing device 900 may include one or more processors 910, a memory 930, a user interface input device 940, a user interface output device 950, and a storage device 560 communicating via a bus 920. The computing device 900 may also include a network interface 970 electrically connected to a network 90. The network interface 970 may transmit or receive signals to or from other entities via the network 90.

The one or more processors 910 may be implemented by various means such as a micro-controller unit (MCU), an application processor (AP), a central processing unit (CPU), a graphic processing unit (GPU), a neural processing unit (NPU), etc., and may be any semiconductor device that executes instructions stored in the memory 930 or a storage device 960. The one or more processors 910 may be configured to implement the functions and methods described above with respect to FIGS. 1 to 9.

The memory 930 and the storage device 960 may include various forms of volatile or non-volatile storage media. For example, the memory may include a read-only memory (ROM) 931 and a random-access memory (RAM) 932. In the present embodiment, the memory 930 may be disposed inside or outside the processor 910, and the memory 930 may be connected to the processor 910 through various means already known.

In some embodiments, at least some of the components or functions of the AI-based wafer rotation device and method according to the embodiments may be implemented as a program or software executed on the computing device 900, and the program or software may be stored on a computer-readable medium.

In some embodiments, at least some of the components or functions of the AI-based wafer rotation device and method according to the embodiments may be implemented using hardware or a circuit of the computing device 900 or may be implemented as separate hardware or a circuit that can be electrically connected to the computing device 900.

The AI-based wafer rotation device, the semiconductor manufacturing equipment units, the models, the modules, the processors, and the memories described herein with respect to FIGS. 1-9 are implemented by or representative of hardware components. Examples of hardware components that may be used to perform the operations described in this application where appropriate include controllers, sensors, generators, drivers, memories, comparators, arithmetic logic units, adders, subtractors, multipliers, dividers, integrators, and any other electronic components configured to perform the operations described in this application. In other examples, one or more of the hardware components that perform the operations described in this application are implemented by computing hardware, for example, by one or more processors or computers. A processor or computer may be implemented by one or more processing elements, such as an array of logic gates, a controller and an arithmetic logic unit, a digital signal processor, a microcomputer, a programmable logic controller, a field-programmable gate array, a programmable logic array, a microprocessor, or any other device or combination of devices that is configured to respond to and execute instructions in a defined manner to achieve a desired result. In one example, a processor or computer includes, or is connected to, one or more memories storing instructions or software that are executed by the processor or computer. Hardware components implemented by a processor or computer may execute instructions or software, such as an operating system (OS) and one or more software applications that run on the OS, to perform the operations described in this application. The hardware components may also access, manipulate, process, create, and store data in response to execution of the instructions or software. For simplicity, the singular term “processor” or “computer” may be used in the description of the examples described in this application, but in other examples multiple processors or computers may be used, or a processor or computer may include multiple processing elements, or multiple types of processing elements, or both. For example, a single hardware component or two or more hardware components may be implemented by a single processor, or two or more processors, or a processor and a controller. One or more hardware components may be implemented by one or more processors, or a processor and a controller, and one or more other hardware components may be implemented by one or more other processors, or another processor and another controller. One or more processors, or a processor and a controller, may implement a single hardware component, or two or more hardware components. A hardware component may have any one or more different processing configurations, examples of which include a single processor, independent processors, parallel processors, single-instruction single-data (SISD) multiprocessing, single-instruction multiple-data (SIMD) multiprocessing, multiple-instruction single-data (MISD) multiprocessing, and multiple-instruction multiple-data (MIMD) multiprocessing.

The methods illustrated in FIGS. 1-11 that perform the operations described in this application are performed by computing hardware, for example, by one or more processors or computers, implemented as described above implementing instructions or software to perform the operations described in this application that are performed by the methods. For example, a single operation or two or more operations may be performed by a single processor, or two or more processors, or a processor and a controller. One or more operations may be performed by one or more processors, or a processor and a controller, and one or more other operations may be performed by one or more other processors, or another processor and another controller. One or more processors, or a processor and a controller, may perform a single operation, or two or more operations.

Instructions or software to control computing hardware, for example, one or more processors or computers, to implement the hardware components and perform the methods as described above may be written as computer programs, code segments, instructions or any combination thereof, for individually or collectively instructing or configuring the one or more processors or computers to operate as a machine or special-purpose computer to perform the operations that are performed by the hardware components and the methods as described above. In one example, the instructions or software include machine code that is directly executed by the one or more processors or computers, such as machine code produced by a compiler. In another example, the instructions or software include higher-level code that is executed by the one or more processors or computer using an interpreter. The instructions or software may be written using any programming language based on the block diagrams and the flow charts illustrated in the drawings and the corresponding descriptions herein, which disclose algorithms for performing the operations that are performed by the hardware components and the methods as described above.

The instructions or software to control computing hardware, for example, one or more processors or computers, to implement the hardware components and perform the methods as described above, and any associated data, data files, and data structures, may be recorded, stored, or fixed in or on one or more non-transitory computer-readable storage media. Examples of a non-transitory computer-readable storage medium include read-only memory (ROM), random-access programmable read only memory (PROM), electrically erasable programmable read-only memory (EEPROM), random-access memory (RAM), dynamic random access memory (DRAM), static random access memory (SRAM), flash memory, non-volatile memory, CD-ROMs, CD-Rs, CD+Rs, CD-RWs, CD+RWs, DVD-ROMs, DVD-Rs, DVD+Rs, DVD-RWs, DVD+RWs, DVD-RAMs, BD-ROMs, BD-Rs, BD-R LTHs, BD-REs, blue-ray or optical disk storage, hard disk drive (HDD), solid state drive (SSD), flash memory, a card type memory such as multimedia card micro or a card (for example, secure digital (SD) or extreme digital (XD)), magnetic tapes, floppy disks, magneto-optical data storage devices, optical data storage devices, hard disks, solid-state disks, and any other device that is configured to store the instructions or software and any associated data, data files, and data structures in a non-transitory manner and provide the instructions or software and any associated data, data files, and data structures to one or more processors or computers so that the one or more processors or computers can execute the instructions. In one example, the instructions or software and any associated data, data files, and data structures are distributed over network-coupled computer systems so that the instructions and software and any associated data, data files, and data structures are stored, accessed, and executed in a distributed fashion by the one or more processors or computers.

While this disclosure includes specific examples, it will be apparent after an understanding of the disclosure of this application that various changes in form and details may be made in these examples without departing from the spirit and scope of the claims and their equivalents. The examples described herein are to be considered in a descriptive sense only, and not for purposes of limitation. Descriptions of features or aspects in each example are to be considered as being applicable to similar features or aspects in other examples. Suitable results may be achieved if the described techniques are performed in a different order, and/or if components in a described system, architecture, device, or circuit are combined in a different manner, and/or replaced or supplemented by other components or their equivalents.

Therefore, in addition to the above disclosure, the scope of the disclosure may also be defined by the claims and their equivalents, and all variations within the scope of the claims and their equivalents are to be construed as being included in the disclosure.

What is claimed is:

1. An artificial intelligence-based wafer rotation method, comprising:
receiving measurement data of a manufacturing process from a data measurement module integrated into manufacturing equipment;
calculating, based on the measurement data, a rotation angle of a wafer for each process step that maximizes manufacturing yield; and
rotating the wafer at the calculated rotation angle in at least one of process steps.

2. The method of claim 1, wherein
the calculating of the rotation angle of the wafer for each process step comprises:
determining different rotation angles applied at each process step to identify defect causes for defects occurring at an initial alignment angle of the wafer.

3. The method of claim 1, wherein
the calculating of the rotation angle of the wafer for each process step comprises:
determining, based on the measurement data, a first process step where a first defective region is detected and a second process step where a second defective region is detected among the process steps; and
determining a first rotation angle for the first process step or a second rotation angle for the second process step such that the first defective region and the second defective region overlap.

4. The method of claim 1, wherein
the rotating of the wafer at the rotation angle of the wafer for each process step comprises:
assigning the calculated rotation angle as a process condition for each process step using a sequence recipe (SEQ RCP).

5. The method of claim 1, wherein
the rotating of the wafer at the rotation angle of the wafer for each process step comprises:
rotating the wafer via an aligner within an Equipment Front End Module (EFEM) at each process step.

6. The method of claim 1, wherein
the measurement data comprises at least one of: critical dimension (CD), optical critical dimension (OCD), thickness (THK), dielectric constant (k value), inspection (INSP), and energy-dispersive spectroscopy (EDS) related to the manufacturing yield, and wherein the data measurement module includes integrated metrology (IM).

7. The method of claim 1, further comprising:
generating an image or coordinating data indicating a defective region of the wafer based on the measurement data.

8. The method of claim 7, wherein
the calculating of the rotation angle of the wafer for each process step comprises:
determining the rotation angle based on the measurement data, the image, or the coordinating data at each process step.

9. The method of claim 1, wherein
the calculating of the rotation angle of the wafer for each process step comprises:
determining a rotation angle required to control a distribution in an etching process step based on film thickness distribution data of the wafer.

10. The method of claim 1, further comprising:
re-collecting second measurement data for each process step after wafer rotation according to the calculated rotation angle; and
recalculating the rotation angle of the wafer for each process step based on the collected second measurement data to further optimize the manufacturing yield.

11. An artificial intelligence-based wafer rotation device, comprising:
a data measurement module that generates measurement data of a manufacturing process;
a rotation angle calculation module that computes a rotation angle of a wafer for each process step to maximize manufacturing yield based on the measurement data; and
a wafer rotation module that rotates the wafer by the calculated rotation angle at least once during each one of process steps.

12. The device of claim 11, wherein
the rotation angle calculation module:
determines different rotation angles applied at each process step to identify defect cause of defects associated with an initial alignment angle of the wafer.

13. The device of claim 11, wherein
the rotation angle calculation module
determines, based on the measurement data, a first process step where a first defective region is detected and a second process step where a second defective region is detected among the process steps; and
determines a first rotation angle for the first process step or a second rotation angle for the second process step such that the first defective region and the second defective region overlap.

14. The device of claim 11, further comprising:
a controller that assigns the calculated rotation angle as a process condition for each process step using a sequence recipe (SEQ RCP).

15. The device of claim 11, wherein
the wafer rotation module
rotates the wafer using an aligner within an Equipment Front End Module (EFEM) at each process step.

16. The device of claim 11, wherein
the data measurement module comprises integrated metrology (IM); and
the measurement data comprises at least one of: critical dimension (CD), optical critical dimension (OCD), thickness (THK), dielectric constant (k value), inspection (INSP), and energy-dispersive spectroscopy (EDS) related to the manufacturing yield.

17. The device of claim 11, wherein
the artificial intelligence model generates an image or coordinating data indicating a defective region of the wafer based on the measurement data.

18. The device of claim 17, wherein
the rotation angle calculation module
determines the rotation angle based on the measurement data, the image, or the coordinating data at each of the process steps.

19. The device of claim 11, wherein
the rotation angle calculation module
calculates a rotation angle required to control a distribution in an etching process step based on film thickness distribution data of the wafer.

20. The device of claim 11, wherein
the rotation angle calculation module
re-collects second measurement data for each process step after wafer rotation according to the calculated rotation angle; and
re-calculates the rotation angle of the wafer for each process step based on the collected second measurement data to further optimize the manufacturing yield.
